(19) United States
(12) Patent Application Publication
(10) Pub. No.: US 2008/0073699 A1
(43) Pub. Date: Mar. 27, 2008

(54) SEMICONDUCTOR DEVICE AND METHOD FOR MANUFACTURING SEMICONDUCTOR DEVICE

(75) Inventors: Kazuhito Nishitani, Kanagawa-ken (JP); Hidehiko Yabuhara, Kanagawa-ken (JP)

Correspondence Address: PEARNE & GORDON LLP, 1801 EAST 9TH STREET, SUITE 1200, CLEVELAND, OH, 44114-3108, US

(73) Assignee: KABUSHIKI KAISHA TOSHIBA, Tokyo (JP)

(21) Appl. No.: 11/689,157

(22) Filed: Mar. 21, 2007

(30) Foreign Application Priority Data
Sep. 25, 2006 (JP) 2006-259313

(51) Int. Cl. H01L 29/788; H01L 21/336

(52) U.S. Cl. 257/321; 438/261; 257/E29.3; 257/E21.422

(57) ABSTRACT

A method for manufacturing a semiconductor device includes: forming a first film on a base body; crystallizing the first film by heating; thinning the crystallized first film; and forming a second film on the thinned first film. The first film is made of a material having a high dielectric constant than silicon oxide. A semiconductor device includes: a silicon substrate; a tunnel insulating film provided on the silicon substrate; a floating gate electrode provided on the tunnel insulating film; a polycrystalline insulating film provided on the floating gate electrode; and a control gate electrode provided on the polycrystalline insulating film. The polycrystalline insulating film has a high dielectric constant than silicon oxide, and the polycrystalline insulating film is made of crystal grains which are substantially monocrystalline in a film thickness direction

### CROSS-REFERENCE TO RELATED APPLICATIONS

This application is based upon and claims the benefits of priority from the prior Japanese Patent Application No. 2006-259313, filed on Sep. 25, 2006; the entire contents of which are incorporated herein by reference.

### BACKGROUND OF THE INVENTION

1. Field of the Invention

This invention relates to a semiconductor device and a method for manufacturing a semiconductor device, and more particularly to a method for manufacturing a semiconductor device applicable to crystallizing high dielectric films used in nonvolatile semiconductor memory devices (e.g. flash memory devices) and a semiconductor device.

2. Background Art

Semiconductor flash memory devices use a silicon-based insulating film as a high-quality insulating film between a floating electrode and a control electrode. With the downscaling and increased integration of devices, thinning the insulating film is required. Even in the amorphous state, the silicon-based insulating film has no problem with leak current characteristics related to data storage capability. However, because of its low dielectric constant, the capacitance between the floating electrode and the control electrode is insufficient, and hence it is difficult to control device parameters such as write voltage. To overcome this, introduction of high dielectric films made of oxides of aluminum, hafnium, lanthanum, or tantalum is under investigation. Use of these types of materials is disclosed in IP 2006-086525A and JP10-189921A, for example.

Although high dielectric films made of oxides of transition metals and the like have high dielectric constant, they have poor leak current characteristics in the amorphous state. Hence crystallization thereof is desirable. However, the crystallization requires a thermal process nearly at 1000° C., and unfortunately, the thermal process deteriorates transistor characteristics. Thus, for the purpose of maintaining transistor characteristics, a method for crystallizing a high dielectric film at low temperatures with reducing thermal budget is required.

### SUMMARY OF THE INVENTION

According to an aspect of the invention, there is provided a method for manufacturing a semiconductor device including: forming a first film on a base body, the first film being made of a material having a high dielectric constant than silicon oxide; crystallizing the first film by heating; thinning the crystallized first film; and forming a second film on the thinned first film.

According to another aspect of the invention, there is provided a semiconductor device including: a silicon substrate; a tunnel insulating film provided on the silicon substrate; a floating gate electrode provided on the tunnel insulating film; a polycrystalline insulating film provided on the floating gate electrode, the polycrystalline insulating film having a high dielectric constant than silicon oxide, and the polycrystalline insulating film being made of crystal grains which are substantially monocrystalline in a film thickness direction; and a control gate electrode provided on the polycrystalline insulating film.

According to another aspect of the invention, there is provided a semiconductor device including: a silicon substrate; a tunnel insulating film provided on the silicon substrate; a floating gate electrode provided on the tunnel insulating film; a polycrystalline insulating film provided on the floating gate electrode, the polycrystalline insulating film having a high dielectric constant than silicon oxide, and a size of crystal grains of the polycrystalline insulating film is larger in a film surface direction than in the film thickness direction; and a control gate electrode provided on the insulating film.

### BRIEF DESCRIPTION OF THE DRAWINGS

FIG. 1 is a process diagram showing the sequence of crystallizing a high dielectric film according to a first embodiment of the invention.

FIG. 2 shows the cross-sectional structure of a film in each step of the process.

FIG. 3 is a schematic diagram that conceptually shows the state of a high dielectric film in this embodiment.

FIG. 4 is a schematic diagram that conceptually shows the state of a high dielectric film in a manufacturing method according to a comparative example.

FIG. 5 is a process diagram showing the sequence of crystallizing a high dielectric film according to a second embodiment of the invention.

FIG. 6 shows the cross-sectional structure of a film in each step of the process.

### DETAILED DESCRIPTION OF THE INVENTION

Embodiments of the invention will now be described with reference to the drawings.

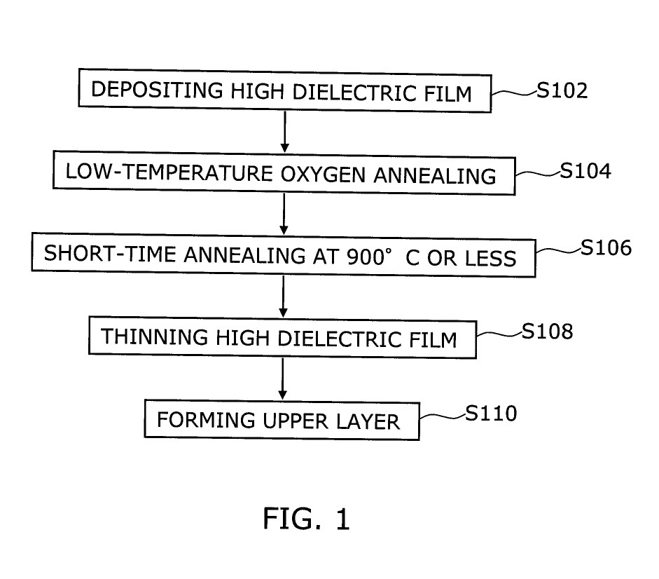

FIG. 1 is a process diagram showing the sequence of a method for manufacturing a semiconductor device according to a first embodiment of the invention.

The method for manufacturing a semiconductor device of this embodiment comprises the steps of depositing a high dielectric film (step S102), low-temperature oxygen annealing (step S104), short-time annealing at 900° C. or less (step S106), thinning the high dielectric film (step S108), and forming an upper layer (step S110).

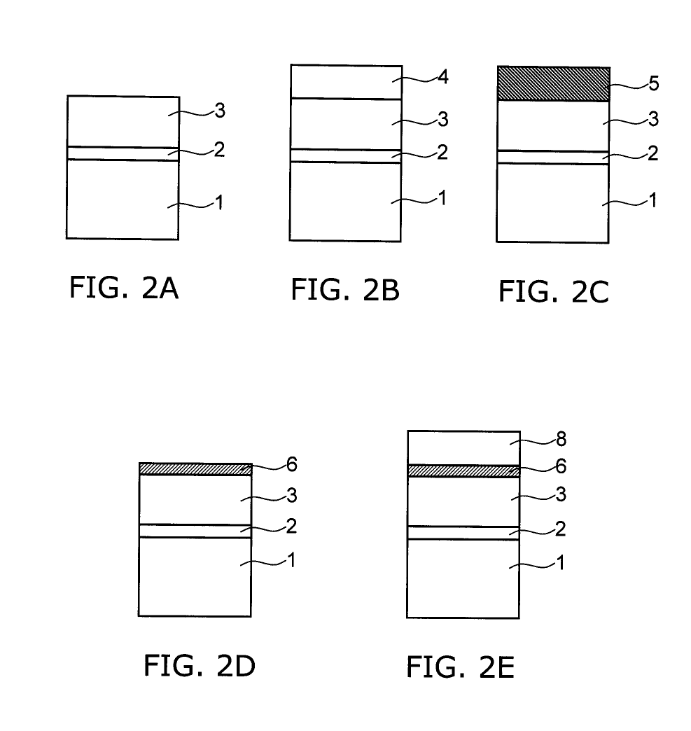

FIGS. 2A to 2E are cross-sectional views of a film in each step of the method for manufacturing a semiconductor device of this embodiment. Here, FIG. 2 shows an example where this embodiment is applied to a semiconductor flash memory device.

Before the sequence shown in FIG. 1, the following process is illustratively completed, and the initial state shown in FIG. 2A has been reached. A tunnel insulating film 2 is formed to a thickness of 10 nm or less on a silicon substrate 1. A floating gate electrode 3 having a thickness of 50 to 100 nm is formed on the tunnel insulating film 2. Furthermore, STI (Shallow Trench Isolation), not shown, for device isolation is appropriately formed. The film structure isolated by STI has a width of e.g. 50 nm or less. Then the substrate is cleaned.

After the foregoing preprocess is completed, a high dielectric film is deposited as shown in FIGS. 1 and 2. The high dielectric film is an IPD (interpoly dielectric) film. Before the high dielectric film is formed, an insulating film, although not shown, made of silicon oxide or the like having a thickness of about 10 nm or less is formed. On this insulating film, an amorphous high dielectric film 4 is formed as shown in FIG. 2B (step S102). The high dielectric film refers to a film made of a material having high dielectric constant than silicon oxide. The material may illustratively be an oxide containing at least one of aluminum, hafnium, lanthanum, and tantalum. The high dielectric film 4 made of such material is formed to a thickness of 10 nm or more. Such thick formation facilitates crystallization in a later step. The reason for this is considered that a thick film has more crystal nuclei than a thin film and facilitates crystallization.

Then, low-temperature oxygen annealing is performed (step S104). That is, because oxygen deficiency occurs in forming the amorphous high dielectric film 4, the oxygen deficiency is complemented.

Next, for crystallizing the amorphous high dielectric film 4, short-time annealing at 900° C. or less is performed in an oxygen and nitrogen atmosphere under a pressure of 1 atmosphere or more (step S106). The annealing time is about 30 seconds. Conventionally, a high temperature of 1000° C. or more is required. However, according to this embodiment, crystallization is possible at a temperature of 900° C. or less. By crystallization, a crystallized high dielectric film 5 is formed as shown in FIG. 2C.

For example, in the case of semiconductor flash memory devices, the required thickness for a high dielectric film is about 2 nm. Therefore the thickly formed and crystallized film is thinned (step S108). Thinning can be performed by dry etching, for example. Specifically, reactive ion etching or other technique is used for etching at a slow rate. As described above, the film is once thickly formed, crystallized, and then thinned. Thus a high dielectric film 6 realized as a crystallized IPD film can be obtained as shown in FIG. 2D. Then, although not shown, an insulating film made of silicon oxide or the like having a thickness of about 10 nm or less is formed. Thus a high dielectric film 6 is formed as an IPD film.

Then a control gate electrode 8, for example, is formed as an upper layer to a thickness of 50 to 100 nm. Thus a laminated structure shown in FIG. 2E is completed.

JP 2006-086525A and JP 10-189921A disclose oxides of aluminum, hafnium, lanthanum, and tantalum used as materials for high dielectric films. However, in JP 2006-086525A and JP 10-189921A, the high dielectric films are only used as they are formed, and different from that obtained in this embodiment.

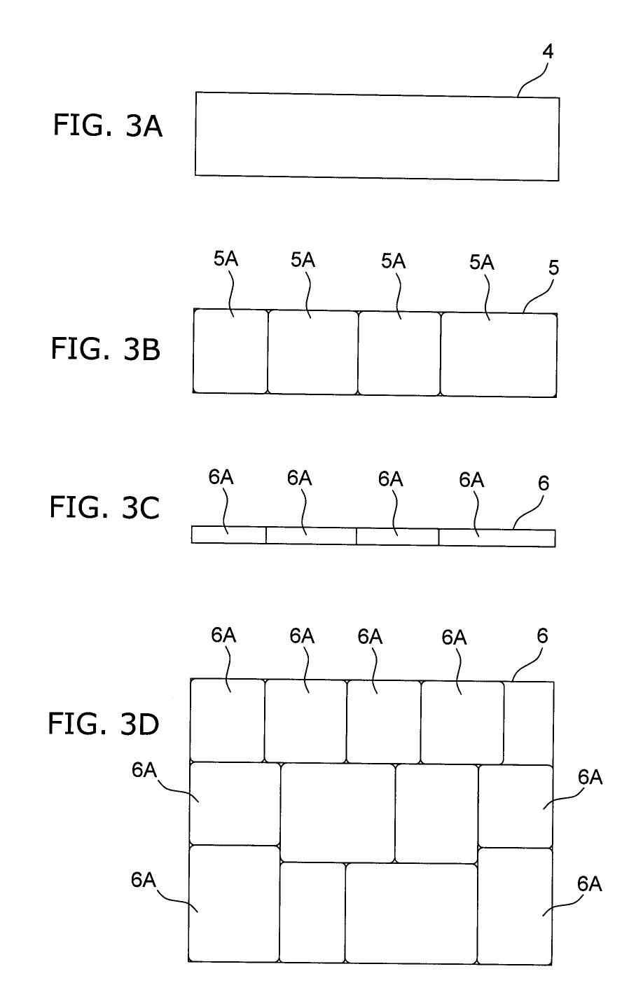

FIG. 3 is a schematic diagram that conceptually shows the state of a high dielectric film in this embodiment. More specifically, FIGS. 3A to 3C are cross-sectional views of the high dielectric film, and FIG. 3D is a plan view of the high dielectric film.

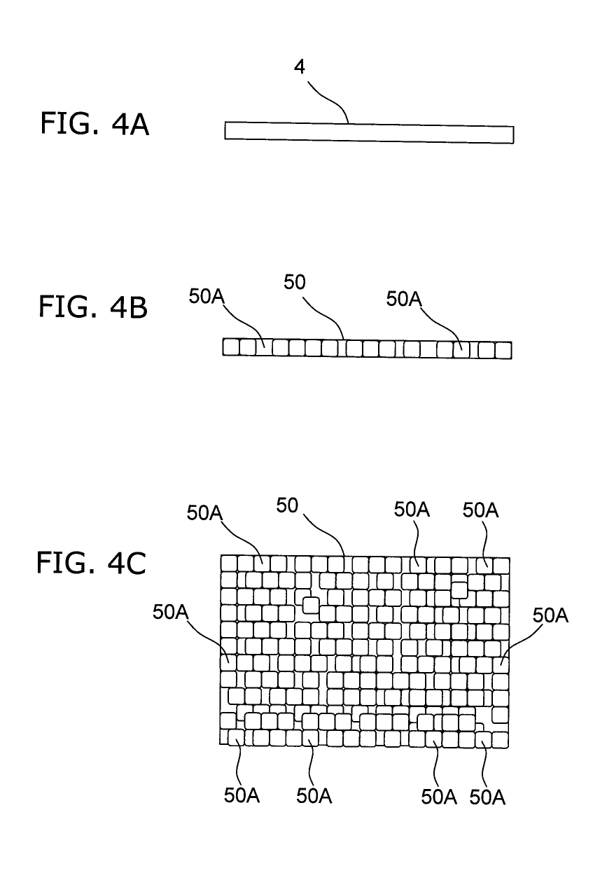

FIG. 4 is a schematic diagram that conceptually shows the state of a high dielectric film in a manufacturing method according to a comparative example. More specifically, FIGS. 4A and 4B are cross-sectional views of the high dielectric film, and FIG. 4C is a plan view of the high dielectric film.

In this embodiment, first, as shown in FIG. 3A, a high dielectric film 4 is deposited (step S102). Here, the high dielectric film 4 is formed to a thickness (e.g. 10 nm) larger than the required film thickness (e.g. 2 nm). The high dielectric film 4, which is deposited by the conventional technique such as CVD or sputtering, is nearly in the amorphous state. Next, it is annealed at a low temperature (e.g. 900° C. or less) for crystallization (step S106). Then, crystallization proceeds in the film thickness direction and in the film surface direction. Thus, as illustrated in FIG. 3B, a polycrystalline high dielectric film 5 made of single crystal grains 5A which are substantially monocrystalline in the film thickness direction is obtained.

Subsequently, the high dielectric film 5 is thinned by etching to obtain a high dielectric film 6 (step S108). Crystal grains are grown also in the film surface direction. Hence, as shown in FIG. 3C, the high dielectric film 6 may be obtained as a polycrystal where the size of the crystal grain 6A is larger in the film surface direction than in the film thickness direction.

On the other hand, in the comparative example shown in FIG. 4, a high dielectric film 4 is deposited to a required thickness (e.g. 2 nm). Then it is annealed at a high temperature (e.g. 1000° C. or more) for crystallization. At this time, crystallization proceeds in the film surface direction as well as in the film thickness direction. However, it is considered that, in response to the thin film thickness, the size of the crystal grain 50A in the film surface direction is often limited as well.

As described above, according to this embodiment, as shown in FIGS. 3C and 3D, the size of the crystal grain 6A of the high dielectric film 6 tends to be large relative to the film thickness. On the contrary, in the comparative example, as shown in FIGS. 4B and 4C, the crystal grain of the high dielectric film 50 after crystallization tends to be relatively small.

That is, according to this embodiment, crystallization can be performed at lower temperatures than in conventional techniques. Furthermore, the high dielectric film after thinning (step S108) tends to have a relatively large crystal grain size in the film surface direction. Note that in FIGS. 3 and 4, the structure of the polycrystal is simplified for convenience. In reality, the shape and size of the crystal grain 6A, 50A are more irregular than as shown.

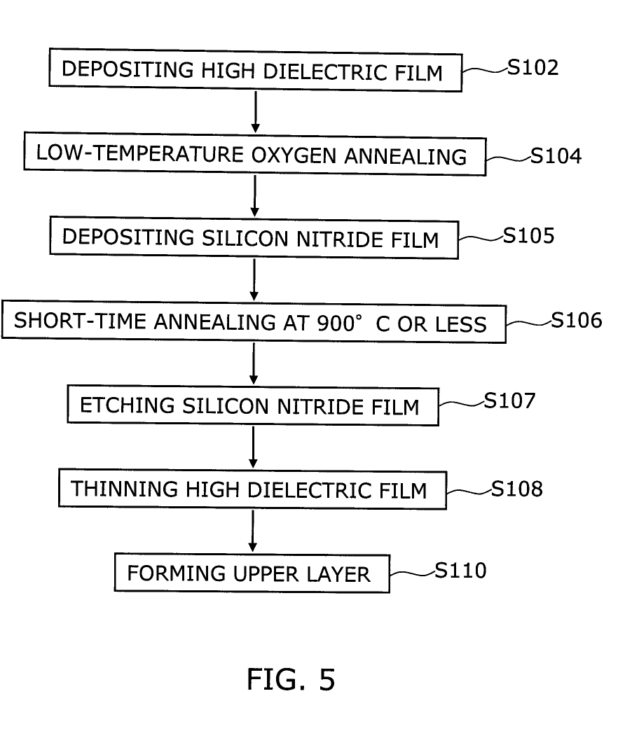

FIG. 5 is a process diagram showing the sequence of a method for manufacturing a semiconductor device according to a second embodiment of the invention.

The method for manufacturing a semiconductor device of this embodiment comprises the steps of depositing a high dielectric film (step S102), low-temperature oxygen annealing (step S104), depositing a silicon nitride film (step S105), short-time annealing at 900° C. or less (step S106), etching the silicon nitride film (step S107), thinning the high dielectric film (step S108), and forming an upper layer (step S110).

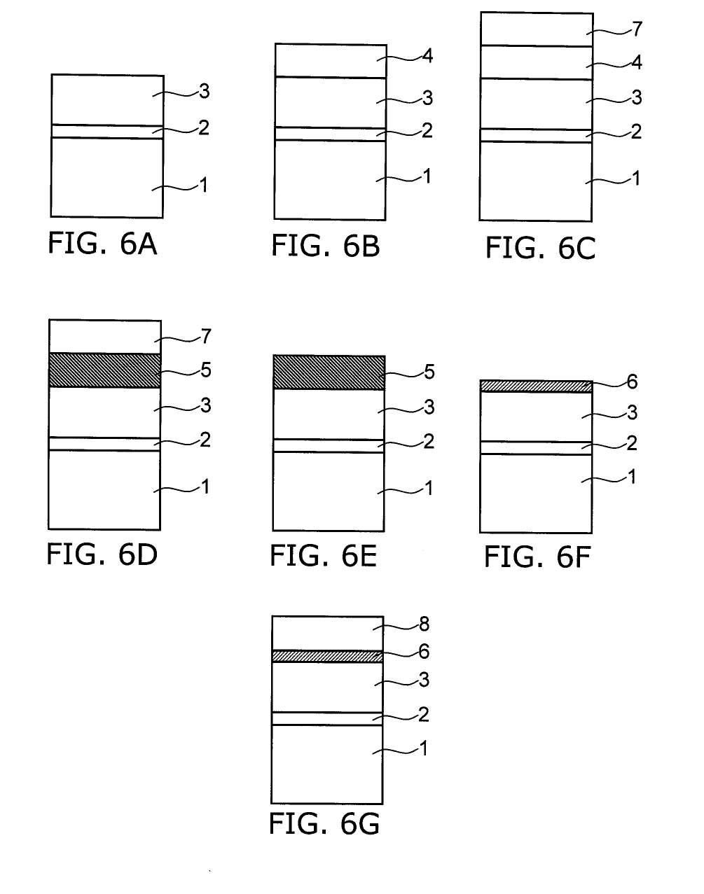

FIGS. 6A to 6G are cross-sectional views in each step of an example where this embodiment is applied to manufacturing a semiconductor flash memory device. This is different from the first embodiment in that a silicon nitride film 7 is additionally formed before the step of crystallizing an amorphous high dielectric film 4, and is etched away after crystallization.

The same steps as those in the first embodiment are not described here. FIG. 6C shows the step of forming a silicon nitride film 7 (step S105). FIG. 6D shows the step of crystallization by short-time annealing (step S106). FIG. 6E shows the step of removing the silicon nitride film 7 (step S107).

The silicon nitride film 7 serves to apply stress to the amorphous high dielectric film 4. The silicon nitride film 7 is formed by depositing a 2-nm thin film at a low deposition rate in a plurality of (e.g. 10) iterations using low-temperature plasma CVD or other technique. A larger stress can be produced by deposition divided into a plurality of iterations in this manner than by continuous deposition. The stress applied to the amorphous high dielectric film 4 by such a silicon nitride film 7 facilitates initial nucleation for crystallization, which enables the crystallization temperature to be decreased to 900° C. or less. Furthermore, thermal budget can be reduced to a low level by using low-temperature plasma CVD in forming the silicon nitride film 7.

Removal of the silicon nitride film (step S107) can be performed by wet etching using a chemical solution such as high-temperature phosphoric acid. This can prevent the underlying high dielectric film 5 from being etched. As the result of these steps, as shown in FIG. 6G, a laminated structure similar to that in the first embodiment is completed.

### EXAMPLE

The method similar to that of the first embodiment was applied to an amorphous high dielectric film 4 of aluminum oxide for the following three film thicknesses: 3 nm, 5 nm, and 10 nm. The degree of crystallization was examined by transmission electron microscopy (TEM) and X-ray diffraction (XRD). For a film thickness of 10 nm, by cross-sectional TEM, a clear lattice fringe was observed throughout the film thickness in a film heated at the crystallization temperature of 900° C. for 30 seconds. That is, it was verified that nearly single crystal grains were formed throughout the film thickness and that the size of this crystal grain in the film surface direction was also 10 nm or more.

On the other hand, for a film thickness of 3 nm, by cross-sectional TEM, no lattice fringe was observed for heat treatment at 900° C. for 30 seconds. By planar TEM, a large number of crystallites having an average grain size of less than 1 nm were observed, with a low degree of crystallization.

TABLE 1 summarizes the measurement results by XRD.

TABLE 1

Time (sec)

| Thickness (nm) | 30 | 60 |
|---|---|---|
| 10 | 900 | |
| 5 | | 900 |
| 3 | 1000 | 1000 |
| | (Crystallites) | |

Crystallization temperature (° C.)

For each pair of film thickness and annealing time, the table shows the annealing temperature at which a diffraction peak specific to Al₂O₃ crystal was observed. In the case of an annealing time of 30 seconds, crystallization occurs at 900° C. for a film thickness of 10 nm. However, for a 3-nm film, only crystallites were obtained even at 1000° C. For a film thickness of 5 nm, crystallization was observed at 900° C. by extending the annealing time to 60 seconds. Furthermore, for a film thickness of 3 nm, it was verified that crystallization occurs at 1000° C. by extending the annealing time to 60 seconds.

From the above results, crystallization of a high dielectric film of aluminum oxide and the like can be performed with reduced thermal budget by forming a film thicker than the finally required film thickness and etching it after crystallization. Specifically, for example, to obtain a crystallized high dielectric film having a film thickness of 2 nm, a high dielectric film of e.g. about 10 nm is formed first. A stress application film may be further introduced on the high dielectric film. The film is crystallized at a low temperature. Then the film is thinned by etching to a predetermined thickness of about 2 nm. Thus, without affecting transistor characteristics, a crystallized high dielectric film can be obtained as an IPD film having a predetermined thickness at a low temperature with reduced thermal budget.

In this example, aluminum oxide is used for the high dielectric film 6. However, as described above, it is also possible to use oxides of hafnium, lanthanum, and tantalum, or oxides in which a plurality of metals are mixed, e.g. HfAₓlO_{y}.

The invention is not limited to application to high dielectric films used in flash memories. Furthermore, the material is not limited to metal oxides. The invention is applicable to forming a crystallized ultrathin film, and also to methods for manufacturing various devices in which a crystallized ultrathin film is used.

1. A method for manufacturing a semiconductor device comprising:
forming a first film on a base body, the first film being made of a material having a high dielectric constant than silicon oxide;
crystallizing the first film by heating;
thinning the crystallized first film; and
forming a second film on the thinned first film.

2. The method for manufacturing a semiconductor device according to claim 1, wherein a thickness of the first film is equal to or greater than 10 nanometers in forming the first film.

3. The method for manufacturing a semiconductor device according to claim 1, further comprising, before the step of crystallizing:
heating in an oxygen-containing atmosphere.

4. The method for manufacturing a semiconductor device according to claim 1, further comprising, before the step of crystallizing:
forming a third film made of silicon nitride on the first film.

5. The method for manufacturing a semiconductor device according to claim 3, wherein the silicon nitride film is formed in a plurality of iterations.

6. The method for manufacturing a semiconductor device according to claim 1, wherein the first film is heated at a temperature not higher than 900° C. in crystallizing the first film.

7. The method for manufacturing a semiconductor device according to claim 1, wherein the first film is heated in an atmosphere including oxygen in crystallizing the first film.

8. The method for manufacturing a semiconductor device according to claim 4, further comprising, between the step of crystallizing and the step of thinning:
removing the silicon nitride film.

9. The method for manufacturing a semiconductor device according to claim 8, wherein the silicon nitride film is removed by a wet etching in removing the silicon nitride.

10. The method for manufacturing a semiconductor device according to claim 1, wherein the base body includes a silicon substrate, a tunnel insulating film provided on the silicon substrate, and a floating gate electrode provided on the tunnel insulating film.

11. The method for manufacturing a semiconductor device according to claim 10, wherein the second film includes a control gate electrode.

12. The method for manufacturing a semiconductor device according to claim 1, wherein the first film comprises an oxide containing at least one of aluminum, hafnium, lanthanum, and tantalum.

13. A semiconductor device comprising:
a silicon substrate;
a tunnel insulating film provided on the silicon substrate;
a floating gate electrode provided on the tunnel insulating film;
a polycrystalline insulating film provided on the floating gate electrode, the polycrystalline insulating film having a high dielectric constant than silicon oxide, and the polycrystalline insulating film being made of crystal grains which are substantially monocrystalline in a film thickness direction; and
a control gate electrode provided on the polycrystalline insulating film.

14. The semiconductor device according to claim 13, wherein a size of the crystal grains is larger in a film surface direction than in the film thickness direction.

15. The semiconductor device according to claim 13, wherein a thickness of the polycrystalline insulating film is less than 10 nanometers.

16. The semiconductor device according to claim 13, wherein the polycrystalline insulating film comprises an oxide containing at least one of aluminum, hafnium, lanthanum, and tantalum.

17. A semiconductor device comprising:
a silicon substrate;
a tunnel insulating film provided on the silicon substrate;
a floating gate electrode provided on the tunnel insulating film;
a polycrystalline insulating film provided on the floating gate electrode, the polycrystalline insulating film having a high dielectric constant than silicon oxide, and a size of crystal grains of the polycrystalline insulating film is larger in a film surface direction than in the film thickness direction; and
a control gate electrode provided on the insulating film.

18. The semiconductor device according to claim 17, wherein a thickness of the polycrystalline insulating film is less than 10 nanometers.

19. The semiconductor device according to claim 17, wherein the polycrystalline insulating film comprises an oxide containing at least one of aluminum, hafnium, lanthanum, and tantalum.

20. The semiconductor device according to claim 17, wherein the polycrystalline insulating film is made by:
forming a first film on the floating gate electrode, the first film being made of the material having the high dielectric constant than silicon oxide;
crystallizing the first film by heating; and
thinning the crystallized first film.
